(19) United States
(12) Patent Application Publication
(10) Pub. No.: US 2019/0390701 A1
(43) Pub. Date: Dec. 26, 2019

(54) FASTENING ELEMENT

(71) Applicant: Patchbox GmbH, Wien (AT)

(72) Inventors: Alexander GENG, Wien (AT); Josef HOFSTÄTTER, Ennsbach (AT)

(21) Appl. No.: 16/466,420

(22) PCT Filed: Dec. 5, 2017
(86) PCT No.: PCT/AT2017/000080

§ 371 Date: Jun. 4, 2019

(30) Foreign Application Priority Data
Dec. 5, 2016 (AT) A 548/2016

(51) Int. Cl. F16B 37/04; F16B 12/10; F16B 29/00; H05K 7/14

(52) U.S. Cl. CPC F16B 37/041; H05K 7/1489; F16B 29/00; F16B 12/10

(57) ABSTRACT

A fastening element comprising a first plate with at least two pin-shaped connection elements extending from the first plate, and a second plate with at least one recess, in particular two recesses, for the pin-shaped connection elements, wherein the at least one recess is formed such that the connection elements are insertable into the at least one recess, and wherein the pin-shaped connection elements comprise stop elements arranged, in particular rigidly arranged, on the same and acting in the longitudinal direction of the connection elements and against which the second plate can be brought into abutment when the connection elements pass through the recess of the second plate.

The invention relates to a fastening element and the use of a fastening element for fastening an angle bracket of a hardware component to a series of holes of a rack.

In network and information technology, a plurality of hardware components and computers are mounted within a rack. In data center operations, yet also in event engineering, laboratory engineering and control engineering, the term “rack” signifies a shelf for electric equipment, which has a standard width of e.g. 19 inch and in which the individual appliances (so-called hardware components) to be mounted in the rack have an appropriate front panel width of e.g. exactly 48.26 cm (19″). The hardware components are each fastened by four screws (2 screws on the right and 2 screws on the left sides) in the series of holes of vertically extending angle brackets near the front edges of the rack.

In general, hardware components are fastened to the series of holes of a rack by means of so-called cage nuts (captive or clip nuts) and screws. Cage nuts are usually square-shaped nuts set in a likewise square-shaped sheet metal cage. The nut can be fastened to a sheet metal via the cage so as to enable also a female thread to be provided in thin metal sheets, where thread-cutting is not possible. The cage of the nut is inserted in a usually likewise square-shaped hole in the series of holes. After this, screws are introduced through the holes formed in the angle bracket of the hardware component to be mounted in the rack and screwed into the cage nuts provided in the series of holes of the rack so as to secure the hardware component to the series of holes of the rack. The cage of the nut can also bee provided with noses able to snap into the square hole in the series of holes of the rack such that the cage plus nut need not be held fast separately during mounting. To this end, the cage nut has to be compressed and inserted in the compressed state into the hole of the series of holes, whereupon the cage nut can be released so as to snap into the hole of the series of holes.

Fastening by means of cage nuts is small-sized and does not offer any support and guidance to the hardware component to be mounted, before the hardware component is secured by means of screws. Moreover, at least two persons are required for mounting hardware components by cage nuts and screws. One person to hold the hardware component in the correct position prior to fixing, and a second person to fix by screws the hardware component held in position. Apart from the increased personnel requirement, cage nuts bear a high risk of injury when inserted into the series of holes, since they have sharp edges and technicians can easily cut themselves during the insertion and compression of the cage nuts. Resides the screwdriver necessary for fastening the screws, additional tools are, moreover, frequently required for inserting the cage nut into the hole of the series of holes of the rack.

The present invention aims to avoid the aforementioned drawbacks.

To solve this object, the fastening element according to the invention comprises a first plate with at least two pin-shaped connection elements extending from the first plate, and a second plate with at least one recess, in particular two recesses, for the pin-shaped connection elements, wherein the at least one recess is formed such that the connection elements are insertable into the at least one recess, and wherein the pin-shaped connection elements comprise stop elements arranged, in particular rigidly arranged, on the same and acting in the longitudinal direction of the connection elements and against which the second plate can be brought into abutment when the connection elements pass through the recess of the second plate.

The fastening element according to the invention guarantees a tool-free, time-saving, effective and non-dangerous mounting of hardware components to be installed in a rack with little personnel expenditure. The configuration according to the invention enables the guidance and temporary holding of hardware components to be installed before the latter are fixed in their final positions, since the connection elements of the fastening element protrude from e series of holes of the rack and the holes of the angle bracket of the hardware component to be mounted thus merely have to be slipped onto the connection elements in order to be held in position. No second person need be available for holding the hardware component in its position during mounting.

On both sides of the rack, one fastening element according to the invention is, moreover, sufficient for mounting a hardware component, since the at least two pin-shaped connection elements of the fastening element simultaneously pass through both holes (one to the right and one to the left of the rack) to which the hardware component is to be secured.

Instead of two recesses in the second plate, a single elongated hole is also conceivable.

The distance between the pin-shaped connection elements corresponds to the distance between the two separate recesses, or the longitudinal extension of the single recess of the second plate, so that the pin-shaped connection elements are able to pass through the recesses simultaneously.

The stop elements, in cooperation with the second plate abutting thereon, serve to temporarily hold the fastening element against the series of holes already prior to screwing on the fastening nuts, the series of holes being disposed or clamped at a narrow distance between the first plate and the second plate.

The fastening element according to the invention is preferably further developed such that the at least one recess is open towards the edge of the second plate such that the connection elements are insertable into the at least one recess transversely to the longitudinal direction of the pins.

Alternatively, the :fastening element according to the invention is further developed such that the at least one recess is formed as a closed opening, preferably as a keyhole-shaped or pear-shaped opening, so that the connection elements are insertable into the at least one recess in the longitudinal direction of the pins.

The fastening element according to the invention is preferably further developed to the effect that the stop elements are each formed by a step resulting from a change in the cross section of the connection element.

In an advantageous manner, the fastening element according to the invention is further developed to the effect that the stop elements are each formed by an annular thickening of the respective connection element.

The fastening element according to the invention may, in particular, be further developed to the effect that the stop elements are each formed by an annular end face of the connection element resulting from a reduction of the cross section.

The stop elements ensure the maintenance of the second plate in the desired position. The recess(es) of the second plate is/are fitted on the connection elements of the first plate, whereby the second plate abuts the stop elements and is held so as to define a gap between the first plate and the second plate, in which gap the series of holes is arranged. If the connection elements are stressed by the weight of the hardware component when inserting the hardware component, a clamping effect is, moreover, produced, which enhances the holding effect even further.

The fastening element according to the invention is preferably further developed to the effect that the connection elements are arranged at a distance of a height unit.

A height unit (HU) is a measuring unit used for racks to describe the height of the hardware component to be mounted. Hardware components with one height unit are denoted as “1HU”, devices with two height units are denoted as “2HU” etc. One height unit corresponds to e.g. 1¾ inch, i.e. 44.45 mm. Device housings measured by height units are designed for mounting in standardized (e.g. 19″) racks. The typical height of a rack is 42 HU.

Due to the preferred distance of the connection elements of one HU, one fastening element on either side of the rack suffices to install a 1 HU hardware component, since the at least two pin-shaped connection elements of the fastening element ensure that the two holes (one to the right and one to the left of the rack) to which the hardware component is to be secured are penetrated simultaneously.

Fastening elements with 4, 6, 8 (or a multiple of 2) connection elements would also be conceivable, each corresponding to a plurality of height units of the strip of holes of the rack, whereby it would be possible to fix several hardware components in the rack by just a single fastening element.

In an advantageous manner, the fastening element according to the invention is further developed to the effect that the connection elements have a first free end each, and the stop element is disposed between the first free end and the first plate.

Such a configuration ensures that, when screwing the fastening nuts onto the free ends of the connection elements, the fastening nuts are pressed against the angle bracket, the angle bracket is pressed against the second plate, and the second plate is pressed against the series of holes, thus causing all the elements, i.e. the angle bracket, the second plate, the series of holes and the first plate, to be braced together.

Alternatively, the fastening element according to the invention can De further developed to the effect that the connection elements each have a first free end and a second free end, and the stop elements are disposed on the second free end or between the second free end and the first plate.

The fastening element according to the invention is preferably further developed to the effect that the connection elements comprise threads.

Threads provided on the connection elements are particularly advantageous for the final fixation of the hardware component, since fastening nuts complementary to the threads can be used for securing the hardware component, which will further facilitate mounting.

In an advantageous manner, the fastening element according to the invention is further developed to the effect that the first thread pitch of the thread is formed as a stop element. The double function of the thread—i.e. for mounting the fastening nuts and as a stop element—makes it possible to renounce the additional formation of a separate stop element.

It may, moreover, be preferably provided that screw nuts, in particular cap nuts, can, furthermore, be screwed onto the free end of the threads.

The use of cap nuts enables an even more effective, tool-free mounting, since, unlike mounting with screws according to the prior art, no screwdriver is required to tighten the screw connection, but the cap nut can just be screwed on by hand.

Furthermore, would be conceivable to provide the cap nut with a corrugated outer side in order to improve the grip and hence further facilitate mounting.

The fastening element according to the invention is preferably further developed to the effect that the first plate and the second plate are formed in one piece.

The configuration of the fastening element in one piece enables an even simpler handling, since just one part rather than two separate parts is necessary to fix a hardware component to be mounted in a rack. The one-piece configuration is, for instance, achieved in that the first and second plates are articulately connected to each other by an angularly bendable web.

A second aspect of the invention relates to the use of the fastening element according to the invention for fastening an angle bracket of a hardware component to a series of holes of a rack.

The use according to the invention of the fastening element enables a tool-free, time-saving, effective and non-dangerous mounting of hardware components to be installed in a rack with little personnel expenditure.

In an advantageous manner, the use according to the invention is further developed to the effect that the connection elements, with their free ends ahead, along with the stop elements are stuck from behind through the holes of the series of holes and the second plate is pushed into the gap present between the series of holes and the stop elements, thus securing the connection elements against falling out of the series of holes.

In the case of the present invention, “from behind” denotes from within the rack, which means that in such a case the connection elements of the first plate are stuck through the series of holes of the rack from within the rack until the connection elements plus stop elements protrude from the series of holes forwards, i.e. in the direction of the outer side of the rack. Outer side means that side of the series of holes or the rack from which the angle brackets of the hardware component are approached to the series of holes during mounting, or from which the hardware component is inserted into the rack. The first plate can then be secured with the second plate, the second plate being pushed between the series of holes and the stop element on the front side.

The use according to the invention can, in particular, be further developed to the effect that the holes provided on angle bracket of the hardware component can be fitted onto the free ends of the connection elements.

The hardware component is thereby correctly positioned and maintained in the correct position until its final fixation in a subsequent step. As already pointed out above, such guidance provided by the connection elements ensures that the presence of a second person holding the hardware component in position during mounting can be obviated.

The use according to the invention as preferably further developed to the effect that screw nuts are, furthermore, screwed onto the free ends of the connection elements, thus bracing together the first plate, the series of holes, the angle bracket of the hardware component and the second plate.

This step serves' to finally fix the hardware component in the rack.

In an alternative manner, the use according to the invention is further developed to the effect that the connection elements, with their second free ends ahead, alongside the stop elements are stuck from the front through the holes of the series of holes, whereby the first plate comes to lie against the series of holes and the stop elements arranged on the second free ends engage the series of holes from behind and the second plate is pushed into the gap present between the series of holes and the stop elements located on the second free ends, thus securing the connection elements against falling out of the series of holes.

In this embodiment, the first free ends of the connection elements are also located outside the rack. The hardware component is again correctly positioned and maintained in the correct position, whereby the presence of a second person during mounting can be obviated.

The use according to the invention may, in particular, be further developed to the effect that screw nuts are, furthermore, screwed onto the first free ends of the connection elements, thus bracing together the first plate, the series of holes, the angle bracket of the hardware component and the second plate.

After this step, the hardware component is fixedly mounted in the rack.

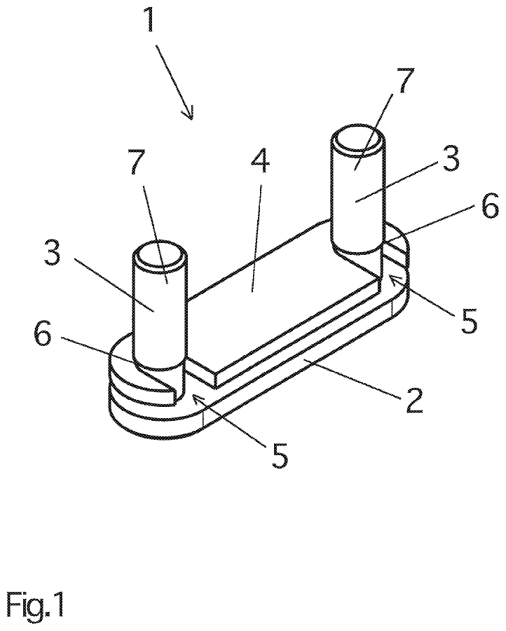

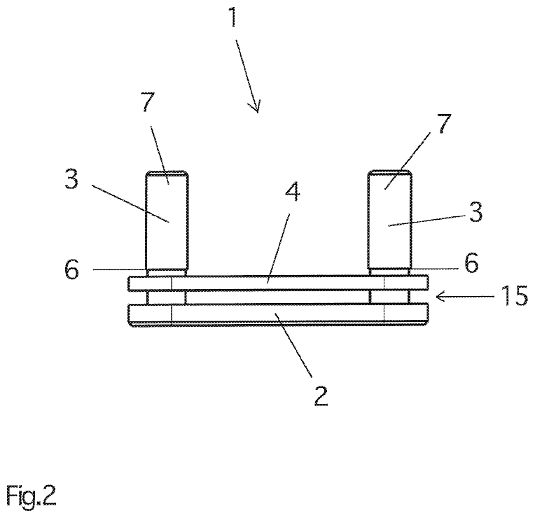

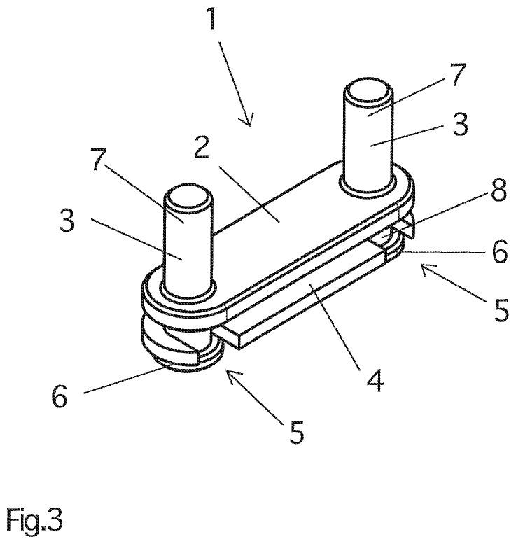

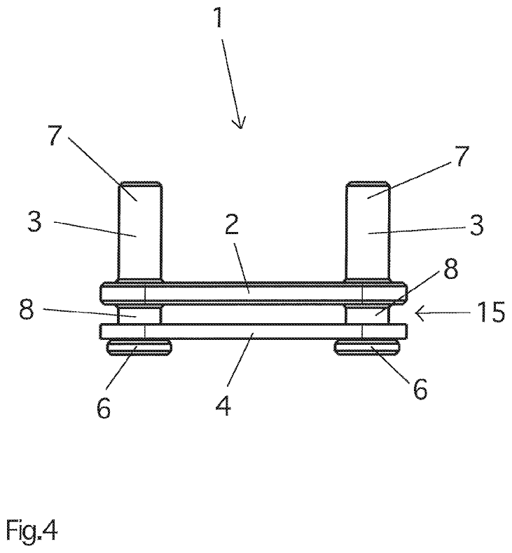

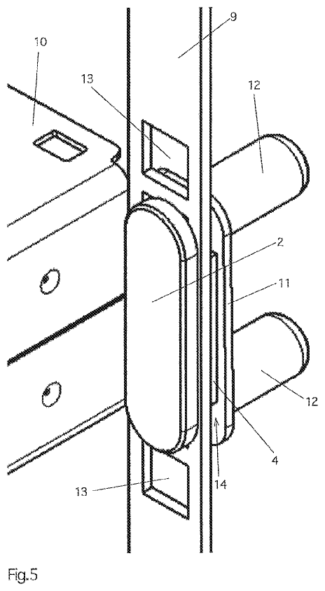

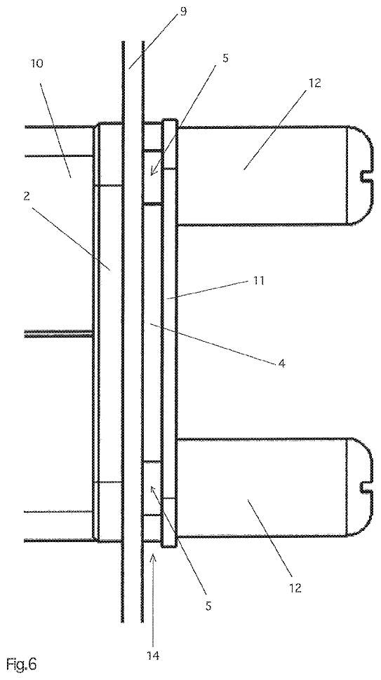

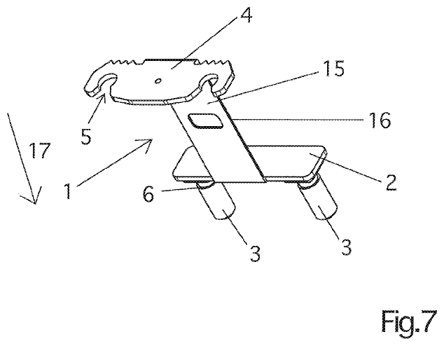

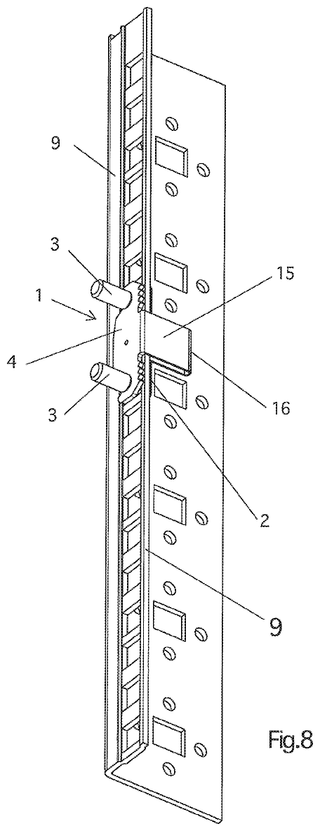

In the following, the invention will be explained in more detail by way of exemplary embodiments schematically illustrated in the drawing. Therein, FIG. 1 is a perspective view of a first embodiment of the fastening element according to the present invention; FIG. 2 is a side view of the first embodiment of the fastening element according to the present invention; FIG. 3 is a perspective view of a second embodiment of the fastening element according to the present invention; FIG. 4 is a side view of the second embodiment of the fastening element according to the present invention; FIG. 5 is a perspective view of the fastening element according to the first embodiment in a state secured to the series of holes with the hardware component installed; FIG. 6 is a side view of the configuration according to FIG. 5; FIG. 7 is a perspective view of the fastening element according to the invention in a third embodiment; and FIG. 8 is a perspective view of the fastening element according to the third embodiment in a state secured to the series of holes.

FIG. 1 depicts the fastening element 1 according to the invention in a first embodiment. The fastening element 1 comprises a first plate 2 with two pin-shaped connection elements 3 extending from the first plate 2, and a second plate 4 with two recesses 5 for the connection elements 3. As is apparent from FIG. 1, the recesses 5 are open towards the edge of the second plate 4.

FIG. 1 depicts the connection elements 3 in a state inserted in the recesses 5.

Furthermore, the stop elements 6 according to the invention are apparent from FIG. 1, each being formed by an end face of the connection element 3 resulting from a reduced cross section of the pin-shaped connection element 3. The connection elements 3 each comprise a first free end 7, and the stop element 6 is disposed between the first free end 7 and the first plate 2. The pin-shaped connection elements 5, between the free end 7 and the stop element 6, are each provided with a thread onto which a fastening nut can be screwed.

FIG. 2 depicts a first embodiment of the fastening element according to the present invention in side view. The reference numerals correspond to the reference numerals chosen in FIG. 1. The gap 15 between the first plate 2 and the second plate 4 is provided for arranging the series of holes of the rack.

FIG. 3 illustrates the fastening element 1 according to the invention in a second embodiment. Also here, the fastening element 1 comprises a first plate 2 with two pin-shaped connection elements 3 extending from the first plate 2, and a second plate 4 with two recesses 5 for the connection elements 3, which are open towards the edge of the second plate 4. The connection elements 3 each have a first free end 7 and a second free end 8, the stop elements 6 being disposed on the second free ends 8 of the connection elements 3 in the form of an annular thickening.

FIG. 3 depicts e connection elements 3 in a state inserted in the recesses 5, wherein it is apparent that the stop elements 6 are each formed by an annular thickening at the end of the respective connection element 3.

FIG. 4 illustrates the second embodiment of the fastening element according to the present invention in side view. The reference numerals correspond to the reference numerals chosen in FIGS. 1 to 3. The gap 15 between the first plate 2 and the second plate 4 is again provided for arranging the series of holes of the rack.

FIG. 5 is a perspective view of the fastening element 1 according to the first embodiment in a screwed state on the series of holes 9, with an installed hardware component 10. Also shown in FIG. 5 is the angle bracket 11 of the hardware component 10.

The connection elements 3 (in this case covered by cap nuts 12) have already been stuck through the holes 13 of the series of holes 9 from behind along with the stop elements 6 (also covered by the cap nuts 12) The second plate 4 is located in the gap present between the series of holes 9 and the stop elements 6 (not visible in FIG. 5), abutting the stop elements 6 of the connection elements 3.

The angle bracket 11 of the hardware component 10 with its holes is already fitted on the free ends 7 of the connection elements 3. By screwing cap nuts 12 onto the free ends 7 of the connection elements 3, the first plate 2, the series of holes 9, the angle bracket 11 of the hardware component 10 and the second plate 4 are braced together.

FIG. 6 depicts a side view of the fastening element 1 according to the first embodiment in the screwed state on the series of holes 9, with an installed hardware component 10. The reference numerals correspond to the reference numerals chosen in FIGS. 1 to 3.

FIG. 7 is a perspective view of the fastening element 1 according to the invention in a third embodiment. The reference numerals correspond to the reference numerals chosen in FIGS. 1 to 6. The first plate 2 and the second plate 4 together are formed as a single part and articulately connected to each other by a bendable web 15. The web 15 only allows for a bend about the hinge 16 in the sense of arrow 17 such that the recesses 5 of the second plate 4, at a full bend of the hinge 16 about 180′, are penetrated by the connection elements 3, thereby abutting the stop elements 6.

FIG. 8 is a perspective view of the fastening element 1 according to the third embodiment in a state secured in the series of holes 9. The reference numerals correspond to the reference numerals chosen in FIGS. 1 to 7. As already explained with reference to FIG. 7, the recesses 5 of the second plate 4—after bending of the hinge 16—by their edges abut the stop elements 6 of the connection elements 3 located on the plate 2, whereby the series of holes 9 is received between the first plate 2 and the second plate 4. The stop elements 6 in cooperation with the second plate 4 abutting the former serve to temporarily hold the fastening element 1 already prior to screwing the fastening nuts onto the series of holes 9, the series of holes 9 being arranged or clamped at a narrow distance between the first plate 2 and the second plate 4.

1. A fastening element comprising a first plate with at least two pin-shaped connection elements extending from the first plate, and a second plate with at least one recess for the at least two pin-shaped connection elements, wherein the at least one recess is formed such that the at least two pin-shaped connection elements are insertable into the at least one recess, and wherein the at least two pin-shaped connection elements comprise stop elements arranged on the same and acting in a longitudinal direction of the at least two pin-shaped connection elements and against which the second plate is configured to be brought into abutment when the at least two pin-shaped connection elements pass through the recess of the second plate, characterized in that the first plate and the second plate are formed in one piece.

2. The fastening element according to claim 1, characterized in that the at least one recess is open towards the edge of the second plate such that the at least two pin-shaped connection elements are insertable into the at least one recess transversely to the longitudinal direction of the at least two pin-shaped connection elements.

3. The fastening element according to claim 1, characterized in that the at least one recess is formed as a closed opening, so that the at least two pin-shaped connection elements are insertable into the at least one recess in the longitudinal direction of the at least two pin-shaped connection elements.

4. The fastening element according claim 1, characterized in that the stop elements are each formed by a step resulting from a change in the cross section of the at least two pin-shaped connection elements.

5. The fastening element according to claim 1, characterized in that the stop elements are each formed by an annular thickening of the respective connection element.

6. The fastening element according to claim 1, characterized in that the stop elements are each formed by an annular end face of the connection element resulting from a reduction of the cross section.

7. The fastening element according to claim 1, characterized in that the at least two pin-shaped connection elements are arranged at a distance of a height unit.

8. The fastening element according to claim 1, characterized in that the at least two pin-shaped connection elements each have a first free end, and the stop element is disposed between the first free end and the first plate.

9. The fastening element according to claim 1, characterized in that the at least two pin-shaped connection elements each have a first free end and a second free end, and the stop elements are disposed on the second free end or between the second free end and the first plate.

10. The fastening element according to claim 1, characterized in that the at least two pin-shaped connection elements each comprises a thread.

11. The fastening element according to claim 10, characterized in that the first thread pitch of the thread is formed as a stop element.

12. The fastening element according to claim 10, characterized in that screw nuts, furthermore, are configured to be screwed onto the free end of the thread.

13. (canceled)

14. The use of a fastening element according to claim 1, for mounting an angle bracket of a hardware component to a series of holes of a rack.

15. The use according to claim 14, characterized in that the at least two pin-shaped connection elements, with their free ends ahead, along with the stop elements are stuck from behind through the holes of the series of holes and the second plate is pushed into a gap present between the series of holes and the stop elements, thus securing the at least two pin-shaped connection elements against falling out of the series of holes.

16. The use according to claim 15, characterized in that the holes provided on the angle bracket of the hardware component are fitted onto the free ends of the at least two pin-shaped connection elements.

17. The use according to claim 16, characterized in that screw nuts are, furthermore, screwed onto the free ends of the at least two pin-shaped connection elements, thus bracing together the first plate, the series of holes, the angle bracket of the hardware component and the second plate.

18. The use according to claim 14, characterized in that the at least two pin-shaped connection elements, with their second free ends ahead, along with the stop elements are stuck from the front through the holes of the series of holes, whereby the first plate comes to lie against the series of holes and the stop elements arranged on the second free ends engage the series of holes from behind and the second plate is pushed into a gap present between the series of holes and the stop elements located on the second free ends, thus securing the at least two pin-shaped connection elements against falling out of the series of holes.

19. The use according to claim 18, characterized in that the holes provided on the angle bracket of the hardware component are fitted onto the first free ends of the at least two pin-shaped connection elements.

20. The use according to claim 19, characterized in that screw nuts are, furthermore, screwed onto the first free ends of the at least two pin-shaped connection elements, thus bracing together the first plate, the series of holes, the angle bracket of the hardware component and the second plate.
